(19) United States
(12) Patent Application Publication
(10) Pub. No.: US 2011/0114181 A1
(43) Pub. Date: May 19, 2011

(54) ECO-FRIENDLY METHOD OF MANUFACTURING QUANTUM DOTS BY USING NATURAL OIL

(76) Inventors: Jae-il Kim, Yongin-si (KR); Suk-Jin Ham, Seoul (KR); Dong-Hyun Cho, Gimhae-si (KR); In-Hyung Lee, Seoul (KR)

(21) Appl. No.: 12/791,309

(22) Filed: Jun. 1, 2010

(30) Foreign Application Priority Data
Nov. 13, 2009 (KR) 10-2009-0109939

(51) Int. Cl. H01L 31/00; C09K 11/02

(52) U.S. Cl. 136/260; 252/301.36; 977/774

(57) ABSTRACT

The present invention relates to a method for manufacturing quantum dots including mixing a Group II metal precursor and a natural oil and increasing temperature thereof and adding a Group VI chalcogenide precursor to the mixed solution and increasing temperature thereof. According to the present invention, use of a natural oil, instead of any artificially synthesized surfactant, allows mass production of eco-friendly quantum dots.

### CROSS-REFERENCE TO RELATED PATENT APPLICATIONS

This application claims the benefit of Korean Patent Application No. 10-2009-0109939, filed on Nov. 13, 2009, in the Korean Intellectual Property Office, the disclosure of which is incorporated herein in their entirety by reference.

### BACKGROUND OF THE INVENTION

1. Field of the Invention

The present invention relates to a method of manufacturing quantum dots including mixing a Group II metal precursor and a natural oil and increasing temperature, and adding a Group VI chalcogenide precursor to the mixed solution and increasing temperature.

2. Description of Related Art

Semiconductor quantum dots having an optical property which is varying with the particle's size have been used in the fields of light emitting diodes (LED) solar cell, bio-labeling and the like.

A conventional method for manufacturing quantum dots is performed through a high temperature pyrolysis of a mixture prepared by adding a metal source and a chalcogenide source into a high temperature surfactant solution. Examples of the surfactant are Tri-n-octylphosphine oxide (TOPO), 1-Octadecene (ODE) and the like. Such a surfactant is usually used in excess amount, compared to an amount of quantum dots to be prepared. However, it is not only costly but also toxic so that it may harm people handling it, be remained on the surface of final quantum dots and a solution used even after washing, and kill cells during bio-labeling tag experiments. Using the conventional method to prepare quantum dots is therefore not proper in view of economy and safety.

As a result, there is high demand to develop a noble method for manufacturing quantum dots economically and safely.

### SUMMARY

An aspect of the present invention provides a method of manufacturing eco-friendly quantum dots in mass scale by using a natural oil in order to resolve the problems associated with the conventional method as described above.

Another aspect of the present invention provides a method of manufacturing quantum dots, including: mixing a Group II metal precursor and a natural oil and increasing temperature thereof; and adding a Group VI chalcogenide precursor to the mixed solution and increasing temperature thereof.

According to an embodiment, the metal precursor may be at least one chosen from zinc, cadmium and mercury.

According to an embodiment, the chalcogenide precursor may be at least one chosen from sulfur, selenium, tellurium and polonium.

According to an embodiment, the natural oil may be a vegetable oil.

According to an embodiment, the vegetable oil may be at least one chosen from soybean oil, olive oil, sunflower oil, grape seed oil, castor oil, rice bran oil, apricot kernel oil, coconut oil, almond oil and camellia oil.

According to an embodiment, the increasing temperature may be carried to the range of 150° C. to 320° C. for 30 seconds to 48 hours.

According to an embodiment, the quantum dots may have a size of 3 nm to 20 nm.

According to an embodiment, a fatty acid may be further added during the mixing step of a Group II metal precursor and a natural oil.

According to an embodiment, the fatty acid may be at least one chosen from oleic acid, stearic acid, lauric acid, tradecylphosphonic acid.

Another aspect of the present invention provides a dye-sensitized solar cell with an absorber layer including the quantum dots prepared according to the method of the present invention.

According to the present invention, use of natural oil, instead of any artificially synthesized surfactant, may allow mass production of eco-friendly quantum dots.

### BRIEF DESCRIPTION OF THE DRAWINGS

FIG. 1 is UV-Vis spectra of cadmium selenide quantum dots prepared according to the method in Example 2 with time.

FIG. 2 is a TEM image of cadmium selenide quantum dots prepared according to the method in Example 2 (5 minutes).

FIG. 3 is TEM images of cadmium selenide quantum dots prepared according to the method in Example 2 with time. TEM images for (a) 10 sec; (b) 30 sec; (c) 90 sec at high T.

### DETAILED DESCRIPTION

The present invention will be described in detail hereinafter.

According to an aspect of the invention, there is provided a method for manufacturing quantum dots, the method including (a) mixing a Group II metal precursor and a natural oil and increasing temperature thereof; and (b) adding a Group VI chalcogenide precursor to the mixed solution and increasing temperature thereof.

According to an embodiment, the Group II metal precursor may be at least one chosen from zinc, cadmium and mercury. Particularly, it may be at least one chosen from dimethyl cadmium (CdMe₂), cadmium oxide (CdO), cadmium carbonate (CdCO₃), cadmium acetate.2 hydrate (Cd(AC)₂.2H₂O), cadmium chloride (CdCl₂), cadmium nitrate (Cd(NO₃)₂), cadmium sulfate (Cd(SO₄)₂), zinc oxide (ZnO), zinc carbonate (ZnCO₃), zinc acetate (Zn(Ac)₂), mercury oxide (Hg₂O), mercury carbonate (HgCO₃) and mercury acetate (Hg(Ac)₂).

According to an embodiment, the chalcogenide precursor may be at least one chosen from sulfur, selenium, tellurium and polonium. Particularly, it may be at least one chosen from tri-n-alkylphosphine sulfide, tri-n-alkenylphosphine sulfide, alkylamino sulfide, alkenylamino sulfide, tri-n-alkylphosphine selenide, tri-n-alkenylphosphine selenide, alkylamino selenide, alkenylamino selenide, tri-n-alkylphosphine telluride, tri-n-alkenylphosphine telluride, alkylamino telluride, alkenylamino telluride, tri-n-alkylphosphine polluride, tri-n-alkenylphosphine polluride, alkylamino polluride, and alkenylamino polluride.

According to an embodiment, the natural oil may be a vegetable oil. According to a conventional method for preparing quantum dots, a surfactant is added to a Group II metal precursor to provide long alkyl chains at the center of quantum dots to improve their dispersion in an organic solvent. However, in the present invention, since a natural oil which already has natural long chains thereon, is used, it is not necessary to use a surfactant and/or any additional material to prepare a metal salt.

The oil used in the present invention can be any natural oil without any limitation, particularly vegetable oils. Examples of the vegetable oil may include soybean oil, olive oil, sunflower oil, grape seed oil, castor oil, rice bran oil, apricot kernel oil, coconut oil, almond oil, camellia oil and a mixture thereof.

Such oils have been widely used in the fields of cosmetics and foods since they are safe and can be manufactured in mass scale. Further, they have cheaper unit price than the conventional purified surfactants so that it lightens the economic burden on bulk purchase. Most of them are edible so that it lowers risks on the human body during the process of manufacturing quantum dots. Such advantages allow mass production of quantum dots safe.

Quantum dots may exhibit luminescence and absorption in the visible light through the control of a reaction time. When quantum dots are prepared according to a conventional method, a long period of reaction time is required at a high temperature in order to obtain quantum dots which have large particle sizes enough to be suitable in the absorption region of a solar cell. However, the method of the present invention allows manufacturing of quantum dots having a desired size by an appropriate control of reaction time and temperature.

According to an embodiment, the increasing temperature in steps (a) and (b) is carried to the range of 150 to 320 for 30 seconds to 48 hours. If it is less than 150, it may be difficult to dissolve a metal precursor. On the other hand, if it is higher than 320° C., it may regenerate the metal precursor which was already melted.

The formation of quantum dots may be identified within several seconds. However, it is apparent to process more than 30 seconds since a reaction may not be conducted enough within less than 30 seconds. It is also apparent to conduct the reaction within 48 hours since after 48 hours, a metal oxide, which was already melted, may be regenerated.

According to an embodiment, the quantum dots may have a size of 3 nm to 20 nm. The size of quantum dots within this range may be controlled by the time of reaction time. In solar cells, when long wavelength quantum dots are required, quantum dots having size of larger than several nanometers are needed. Such quantum dots having this size may be manufactured according to the present invention.

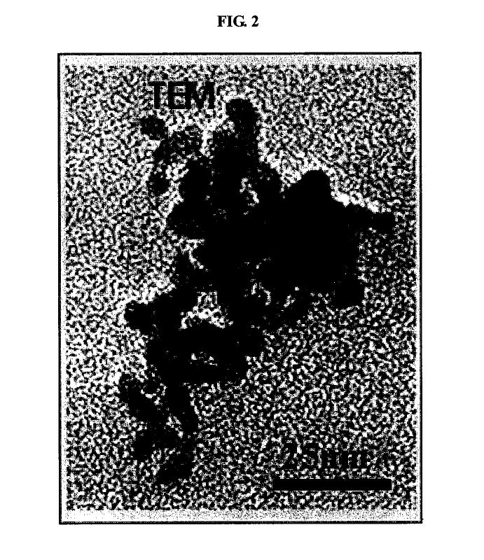

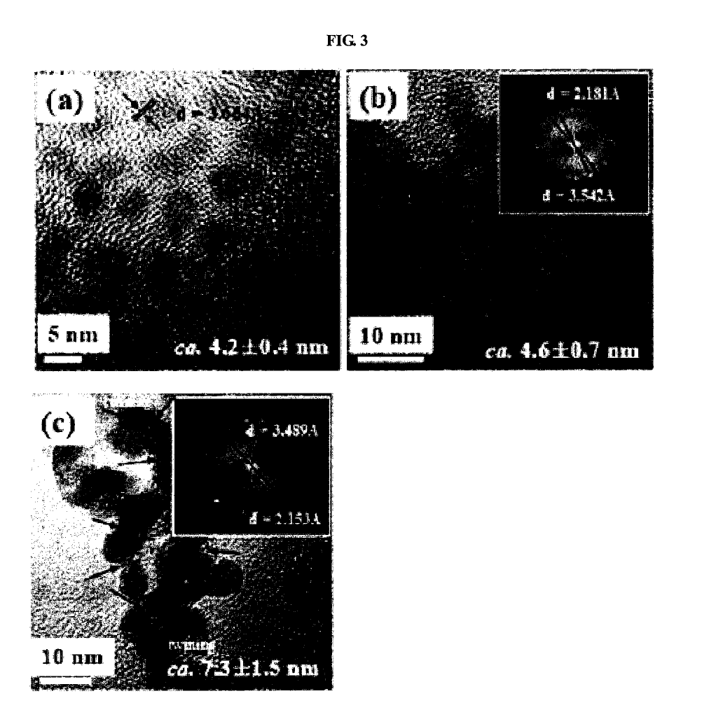

FIGS. 2 and 3 are TEM ((Transmission electron Microscope) images of cadmium selenide quantum dots prepared according to an embodiment of the present invention. As shown in FIG. 2, the quantum dots prepared according to the present invention have a size of several nanometers and look as polycrystal forms to which quantum dots are aggregated with time. Further, the crystals show abnormal growths with time such as twining and stacking fault. FIG. 3(c) shows twining crystals of quantum dots. Such various polycrystal forms may have advantages to be suitable for solar cells. The solar cell utilizes quantum dots as a channel to transfer electrons generated after light absorption. In this case, the quantum dots having organic materials on the surface lower electric conductivity because such organic materials on the surface functions as an insulator. However, the quantum dots prepared according to the method of the present invention may reduce the effect of those organic materials on the surface by having the shape of aggregated large quantum dots so that the transfer of electrons may be increased. As a result, when the quantum dots prepared according to the method of the present invention are used in solar cells, it may exhibit excellent efficiency of the cell. The overall dark image of quantum dots may confirm they are suitable to the absorption range of solar cells.

According to an embodiment, when a metal precursor and a natural oil are mixed, a fatty acid may be additionally added. When a fatty acid is additionally added, it may further stabilize the metal precursor. Examples of the fatty acid may include stearic acid, oleic acid, tradecylphosphonic acid, lauric acid and the like.

Another aspect of the present invention, there is provided a dye-sensitized solar cell with an absorber layer including the quantum dots prepared by the above-mentioned method.

Hereinafter, although more detailed descriptions will be given by Examples, those are only for explanation and there is no intention to limit the invention.

A soybean oil and an olive oil used in Examples below were 100% edible soybean oil and 100% edible olive oil which were purchased from a grocery store.

### Example 1

### Preparation of Cadmium Selenide (CdSe) Quantum Dots Using Soybean Oil

Cadmium oxide (CdO) 128 mg and soybean oil 25 ml were placed into a three-necked round bottomed flask and maintained at 180° C. for 30 minutes under vacuum. When cadmium oxide was completely dissolved and the mixed solution was turned to a clear one, nitrogen gas was charged to the reaction flask and 1M trioctylphosphine selenide 1 ml was added. The reaction solution was heated to 270° C. and maintained at that temperature for 30 minutes to produce cadmium selenide quantum dots.

### Example 2

### Preparation of Cadmium Selenide Quantum Dots Using Soybean Oil

Cadmium oxide (CdO) 128 mg, oleic acid 1.0 ml, and soybean oil 25 ml were placed into a three-necked round bottomed flask and maintained at 180° C. for 30 minutes under vacuum. When cadmium oxide was completely dissolved and the mixed solution was turned to a clear one, nitrogen gas was charged to the reaction flask and 1M trioctylphosphine selenide 1 ml was added. The reaction solution was heated to 270° C. and maintained at that temperature for 30 minutes to produce cadmium selenide quantum dots.

### Example 3

### Preparation of Cadmium Selenide Quantum Dots Using Soybean Oil

Cadmium oxide (CdO) 56 mg, stearic acid 0.5 g, and soybean oil 25 ml were placed into a three-necked round bottomed flask and maintained at 180° C. for 30 minutes under vacuum. When cadmium oxide was completely dissolved and the mixed solution was turned to a clear one, nitrogen gas was charged to the reaction flask and 1M trioctylphosphine selenide 0.5 ml was added. The reaction solution was heated to 290° C. and maintained at that temperature for 30 minutes to produce cadmium selenide quantum dots.

### Example 4

### Preparation of Cadmium Selenide Quantum Dots Using Soybean Oil

Cadmium oxide (CdO) 126 mg, oleic acid 1.0 ml, and soybean oil 25 ml were placed into a three-necked round bottomed flask and maintained at 180° C. for 30 minutes under vacuum. When cadmium oxide was completely dissolved and the mixed solution was turned to a clear one, nitrogen gas was charged to the reaction flask and 1M trioctylphosphine selenide 1 ml was added. The reaction solution was heated to 270° C. and maintained at that temperature for 30 minutes to produce cadmium selenide quantum dots.

### Example 5

### Preparation of Cadmium Selenide Quantum Dots Using Soybean Oil

Cadmium oxide (CdO) 128 mg, tradecylphosphonic acid 1 g, and soybean oil 25 ml were placed into a three-necked round bottomed flask and maintained at 180° C. for 30 minutes under vacuum. When cadmium oxide was completely dissolved and the mixed solution was turned to a clear one, nitrogen gas was charged to the reaction flask and 1M trioctylphosphine selenide 1 ml was added. The reaction solution was heated to 270° C. and maintained at that temperature for 30 minutes to produce cadmium selenide quantum dots.

### Example 6

### Preparation of Cadmium Selenide Quantum Dots Using Olive Oil

Cadmium oxide (CdO) 128 mg and olive oil 25 ml were placed into a three-necked round bottomed flask and maintained at 180° C. for 30 minutes under vacuum. When cadmium oxide was completely dissolved and the mixed solution was turned to a clear one, nitrogen gas was charged to the reaction flask and 1M trioctylphosphine selenide 1 ml was added. The reaction solution was heated to 270° C. and maintained at that temperature for 30 minutes to produce cadmium selenide quantum dots.

### Example 7

### Preparation of Cadmium Selenide Quantum Dots Using Olive Oil

Cadmium oxide (CdO) 126 mg, oleic acid 1.0 ml, and olive oil 25 ml were placed into a three-necked round bottomed flask and maintained at 180° C. for 30 minutes under vacuum. When cadmium oxide was completely dissolved and the mixed solution was turned to a clear one, nitrogen gas was charged to the reaction flask and 1M tributylphosphine selenide 1 ml was added. The reaction solution was heated to 270° C. and maintained at that temperature for 30 minutes to produce cadmium selenide quantum dots.

### Example 8

### Preparation of Cadmium Selenide Quantum Dots Using Olive Oil

Cadmium oxide (CdO) 128 mg, stearic acid 1 g, and olive oil 25 ml were placed into a three-necked round bottomed flask and maintained at 180° C. for 30 minutes under vacuum. When cadmium oxide was completely dissolved and the mixed solution was turned to a clear one, nitrogen gas was charged to the reaction flask and 1M trioctylphosphine selenide 1 ml was added. The reaction solution was heated to 270° C. and maintained at that temperature for 30 minutes to produce cadmium selenide quantum dots.

### Experimental Example

### Absorption Spectrum and TEM Image of Cadmium Selenide Quantum Dots

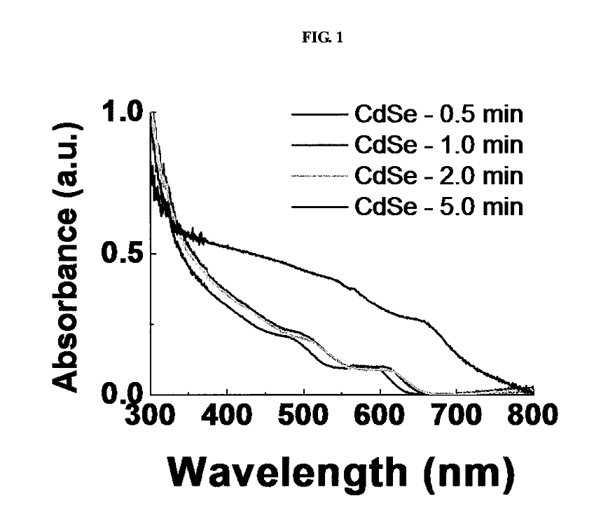

FIG. 1 shows UV-Vis spectra of the quantum dots prepared according to Example 2 with time. It is noted that absorbance and luminescence of the quantum dots change with time (30 seconds, 1 minute, 2 minutes, and 5 minutes). It is also noted that growth of particles is slow in the beginning and increases significantly after a certain time. As determined in the spectra, the quantum dots prepared according to the present invention are light absorptive elements applicable to absorb across the visible range so that it is noted that such light absorptive elements have broader absorption wavelength range than photonic elements prepared by the conventional method.

FIG. 2 shows a TEM image of the quantum dots prepared according to Example 2 at 5 minutes. Aggregation between quantum dots is observed and it looks dark overall by absorbing light. It indicates that they are appropriate light absorptive elements.

FIG. 3 shows TEM images of quantum dots prepared according to Example 4 with time in which (a) is an image of quantum dots after 10 seconds, (b) is after 30 seconds, and (c) is after 90 seconds. A particle size is increased from about 3 nm to about 9 nm. A gap (d) between crystal lattices is gradually decreased and aggregation of crystals is observed. The (c) image shows twining illustrating abnormal growth of crystals. It is thus noted that it is a material having excellent efficiency of solar cell with improved electron transference because of the shape of aggregated large quantum dots.

While it has been described with reference to particular embodiments, it is to be appreciated that various changes and modifications may be made by those skilled in the art without departing from the spirit and scope of the embodiment herein, as defined by the appended claims and their equivalents.

What is claimed is:

1. A method for manufacturing quantum dots comprising:
(a) mixing a Group II metal precursor and a natural oil and increasing temperature thereof; and
(b) adding a Group VI chalcogenide precursor to the mixed solution and increasing temperature thereof.

2. The method of claim 1, wherein the Group II metal precursor is at least one selected from the group consisting of zinc, cadmium and mercury.

3. The method of claim 1, wherein the Group VI chalcogenide precursor is at least one selected from the group consisting of sulfur, selenium, tellurium and polonium.

4. The method of claim 1, wherein the natural oil is a vegetable oil.

5. The method of claim 4, wherein the vegetable oil is at least one selected from the group consisting of soybean oil, olive oil, sunflower oil, grape seed oil, castor oil, rice bran oil, apricot kernel oil, coconut oil, almond oil and camellia oil.

6. The method of claim 1, wherein the increasing temperature is carried to the range of 150 to 320 for 30 seconds to 48 hours.

7. The method of claim 1, wherein in step (a), a fatty acid is further added.

8. The method of claim 7, wherein the fatty acid is at least one selected from the Group consisting of oleic acid, stearic acid, lauric acid, and tradecylphosphonic acid.

9. The method of claim 1, wherein the quantum dots has a size of 3 nm to 20 nm.

10. A dye-sensitized solar cell with an absorber layer comprising the quantum dots prepared by the method of claim 1.
